(19) United States
(12) Patent Application Publication
(10) Pub. No.: US 2026/0023646 A1
(43) Pub. Date: Jan. 22, 2026

(54) PHYSICAL MEMORY BLOCK HEALTH BASED VIRTUAL BLOCK

(71) Applicant: Microchip Technology Incorporated, Chandler, AZ (US)

(72) Inventors: Hayes Hsueh, San Jose, CA (US); Pitamber Shukla, San Jose, CA (US); Srinivas Yelisetti, Fremont, CA (US)

(73) Assignee: Microchip Technology Incorporated, Chandler, AZ (US)

(21) Appl. No.: 18/940,056

(22) Filed: Nov. 7, 2024

Related U.S. Application Data
(60) Provisional application No. 63/674,175, filed on Jul. 22, 2024.

(51) Int. Cl. G06F 11/10

(52) U.S. Cl. CPC G06F 11/1016; G06F 11/1004

(57) ABSTRACT

Non-transitory computer readable media may include instructions stored thereon, that when executed by at least one processor, cause the at least one processor to collect read errors of a plurality of physical blocks, a first subset of said plurality of physical blocks being formed into a virtual block; determine respective health grades for the plurality of physical blocks based on the collected read errors; and based on the respective health grades, reform the virtual block into a reformed virtual block, said reformed virtual block including a second subset of the plurality of physical blocks.

### CROSS-REFERENCE TO RELATED APPLICATIONS

The current patent application claims the benefit under 35 U.S.C. § 119 (e) of the priority date of U.S. Provisional Application Ser. No. 63/674,175; titled “PHYSICAL NAND BLOCK HEALTH BASED VIRTUAL BLOCK”; and filed Jul. 22, 2024. The Provisional Application is hereby incorporated by reference, in its entirety, into the current patent application.

### TECHNICAL FIELD

Various examples of the present disclosure relate to dynamically forming virtual blocks based on physical memory block health.

### BACKGROUND

Physical blocks of a memory device may include healthy and unhealthy physical blocks. The unhealthy physical blocks may negatively impact performance due to early retirement. Unhealthy physical blocks may produce read errors that trigger an error recovery process and increase read latency. Unhealthy blocks may produce errors at a high rate (i.e. higher than healthy blocks), increase an amount of time spent on error correction, and reduce the lifetime of the memory device. Data retention errors and program errors caused by unhealthy physical blocks may trigger garbage collection processes that may increase write amplification. Increased write amplification may increase program/erase (P/E) cycles for the physical blocks, decrease write throughput, and increase read and write latency. Increased P/E cycles cause the physical blocks to degrade which may reduce the lifespan of the memory device.

This background discussion is intended to provide information related to the present invention which is not necessarily prior art.

### SUMMARY OF THE INVENTION

According to various examples of the present disclosure, non-transitory computer readable media may include instructions stored thereon, that when executed by at least one processor, cause the at least one processor to: collect read errors of a plurality of physical blocks, a subset of said plurality of physical blocks being formed into a virtual block; determine respective health grades for the plurality of physical blocks based on the collected read errors; and based on the respective health grades, reform the virtual block into a reformed virtual block, said reformed virtual block including a second subset of the plurality of physical blocks.

According to various examples of the present disclosure, a system may include a plurality of physical blocks and a controller. A first subset of the plurality of physical blocks may be formed into a virtual block. The controller may include a memory and at least one processor. The memory may include instructions that, when executed by the at least one processor, cause the at least one processor to: collect read errors of the plurality of physical blocks; determine respective health grades for the plurality of physical blocks based on the collected read errors; and, based on the respective health grades, reform the virtual block into a reformed virtual block, said reformed virtual block including a second subset of the plurality of physical blocks.

According to various examples of the present disclosure, a computer-implemented method may include: collecting read errors of a plurality of physical blocks, a subset of said plurality of physical blocks being formed into a virtual block; determining respective health grades for the plurality of physical blocks based on the collected read errors; and, based on the respective health grades, reforming the virtual block into a reformed virtual block, said reformed virtual block including a second subset of the plurality of physical blocks.

### BRIEF DESCRIPTION OF THE DRAWINGS

FIG. 1 illustrates an example system for forming virtual blocks based on physical memory block health;

FIG. 2 illustrates an example data storage system of the system of FIG. 1;

FIG. 3 illustrates an example non-volatile memory (NVM) media of the system of FIG. 1;

FIG. 4 illustrates example virtual blocks formed based on physical memory block health;

FIG. 5 illustrates an example method for forming virtual blocks based on physical memory block health; and

FIG. 6 illustrates an example computing system connected to a communication network.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In various examples of the present disclosure, a plurality of virtual blocks of a memory device may be dynamically reformed based on physical memory block health. The memory device may be part of a data storage system. The data storage system may be connected to a host system. In various examples, the data storage system may be connected to the host system by wired or wireless means. In various examples, the data storage system may be connected to more than one host system, such as in a multi-tenant environment, without limitation.

The data storage system may include a controller and the memory device. The controller may be operable to manage storage and retrieval of data to and from the memory device. The host system may send data to the data storage system for storage in the memory device. The host system may send a read request to the data storage system. The read request may indicate data to be retrieved from the memory device and sent back to the host system. The controller may process the read request and retrieve the data from the memory device.

In various examples, the memory device may be a solid state drive (SSD) including a plurality of non-volatile memory (NVM) media (e.g., NAND-based memory media) for data storage. In various examples, the NVM media may include chip enable (CE) ports which may also be referred to as targets. Examples may be used in single-level cell (SLC) systems as DRAM buffering for persistent data storage, but can also be used in higher level cell systems, such as triple-level cell (TLC) systems and quadruple-level cell (QLC) systems. Applications include high performance computing (HPC), data transfer for AI, and data center solutions (DCS).

The NVM media may respectively include a local controller and a plurality of dies. Each die may be referred to as a logical unit (LUN). Each LUN may include a plurality of planes. Each plane may include a plurality of physical blocks.

The controller may organize the physical blocks of the NVM media into a plurality of virtual blocks. A virtual block is a collection of physical blocks across all LUNs. In various examples, a virtual block may be formed to include one physical block from each plane of each LUN. The size of a virtual block may be (#Channels)×(#Targets per channel)×(#LUNs per target)×(#planes per LUN)×(one (1) block/LUN). In an example, an example virtual block may include sixteen (16) channels, eight (8) targets per channel, two (2) LUNs per target, and two (2) planes per LUN, for a total of five hundred twelve (512) physical blocks. The example memory device may support a plurality of virtual blocks respectively including five hundred twelve (512) physical blocks. Additionally, the example virtual block may be further segmented into smaller virtual blocks. For example, the example memory device may support four (4) virtual blocks having a respective size of one hundred twenty-eight (128) physical blocks. In another example, the memory device may support eight (8) virtual blocks having respective sizes of sixty-four (64) blocks. It would be appreciated by one of ordinary skill in the art that a memory device may include more or less channels, targets, LUNs, and planes. The virtual blocks may be formed to include more or less physical blocks depending on the capacity of the memory device.

Each physical block may include a plurality of physical pages. A virtual block comprises multiple virtual pages. A virtual page is a collection of physical pages across all LUNs in a virtual block. A virtual page may be a redundant array of independent disks (RAID) stripe which contains one or two XOR parity pages. A RAID is a way of storing the same data in different places on multiple SSDs to protect data in the case of a drive failure. The number of virtual pages in a virtual block is equal to the number of physical pages in a single block. Similarly, a virtual word line (WL) is a collection of physical WLs across all LUNs in a virtual block. A flash transition layer (FTL) of the controller may manage the physical blocks in a virtual block unit. The FTL may manage a list of virtual blocks according to their states (i.e., free, open, used).

Each virtual block may include respective physical blocks from various LUNs of the targets. For example, a virtual block may include one physical block from each LUN of each target. During operation, some of the physical blocks may produce read errors. The read errors may include uncorrectable read errors and correctable read errors. Uncorrectable read errors may include memory wear or endurance errors. Correctable read errors may include program disturb, read disturb, over-programming, and retention errors.

In various examples, the read errors may be collected by the controller. The collected read errors may include read error information. The read error information may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. Additionally or alternatively, the collected read errors may include information associated with the physical blocks, such as a program/erase cycle count, usage statistics, and/or other relevant information. The controller may determine a health grade of each physical block based on the collected read errors.

In various examples, the physical blocks of a virtual block may wear down at different rates as data is written to and read from different physical blocks at different times and at different rates. The health grades may indicate that certain physical blocks of the virtual block are healthy while other physical blocks of the virtual block are unhealthy. Unhealthy physical blocks may negatively impact the operation of the healthy physical blocks. For example, preventative garbage collection (GC) may be utilized by the controller to move data from a particular virtual block to another virtual block due to errors caused by unhealthy physical blocks of the particular virtual block. Errors caused by unhealthy blocks may increase write amplification. Increased write amplification may increase read latency and reduce the overall efficiency of the memory device. Unhealthy physical blocks may cause read errors that trigger an error recovery process and increase read latency. Unhealthy physical blocks may be retired sooner than healthy physical blocks which may impact write performance when a sufficient amount of healthy blocks of a virtual block are not available.

In various examples, the controller may dynamically reform virtual blocks based on the health grades. For example, a virtual block may include a first subset of physical blocks of a plurality of physical blocks in the memory device. The virtual block may be reformed to include a second subset of the plurality of physical blocks, with the second subset including some or none of the physical blocks that were in the first subset.

A reformed virtual block may include physical blocks having health grades within a threshold range of each other. The controller may determine the health grades based on the collected read errors. In an example, physical blocks producing zero or very few read errors may be given a health grade having a value of one (1). The health grade having the value of one (1) may indicate perfectly or mostly healthy physical blocks. Physical blocks producing uncorrectable read errors or a large number of correctable read errors compared to other physical blocks may be given a health grade having a value of nine (9). The health grade having the value of nine (9) may indicate blocks that may need to be retired or are close to retirement. In this manner, the controller may determine health grades having values between one (1) and nine (9) for each physical block based on different thresholds corresponding to the collected read errors. In an example, the controller may reform a first virtual block to include a set of physical blocks having health grades of 1.

Each virtual block may be dynamically reformed based on the health grades of the physical blocks. Each reformed virtual block may include a set of physical blocks having the same health grades or health grades within a threshold range of each other. Accordingly, write amplification may be decreased, which, in turn, may increase write throughput, decrease read and write latency, and extend the lifespan of the memory device.

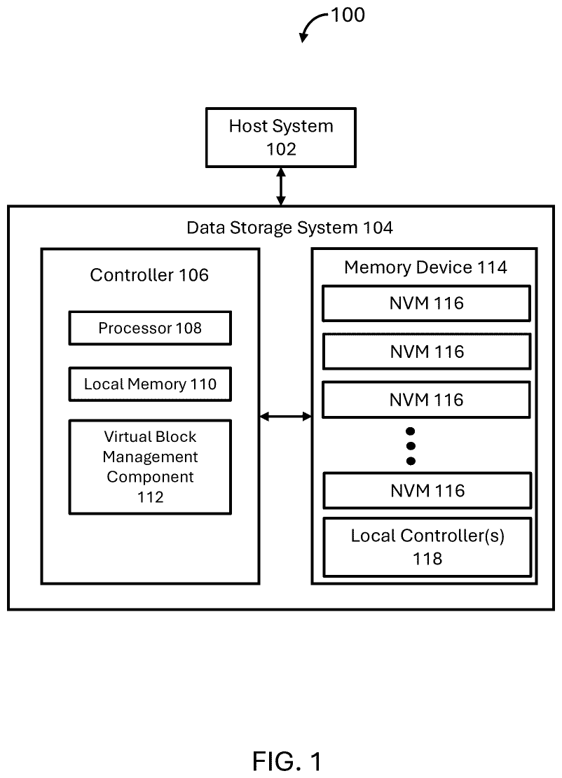

FIG. 1 illustrates an example system 100 including a host system 102 and a data storage system 104. The data storage system 104 may include a controller 106. The controller 106 may include a processor 108, a local memory 110, and a virtual block management component 112. The data storage system 104 may also include a memory device 114. The memory device 114 may include a plurality of non-volatile memory (NVM) media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to provide data protection and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

The virtual block management component 112 may correspond to a flash transition layer (FTL) operable to manage and reform virtual blocks of the NVM media 116. Each virtual block may include a plurality of physical blocks across all logical units (LUNs) of the NVM media 116. Each LUN may include a subset of the physical blocks. In an example, each virtual block may include one physical block from each subset of each LUN. The virtual block management component 112 may collect read errors produced by the physical blocks during read operations of the NVM media 116. The read operation may include a read operation performed in response to a request received form the host system 102 and/or a background scan performed by the virtual block management component 112. The background scan may perform background read operations to detect and collect read errors produced by respective physical blocks of the plurality of blocks. It would be appreciated by one of ordinary skill in the art that various different background scans, such as a patrol read scan or another dedicated background read scan, may be utilized to collect the read errors. The collected read errors may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. The collected read errors may include additional information associated with the physical blocks, such as a program/erase cycle count, usage statistics, and/or other relevant information. Accordingly, the virtual block may be reformed to include physical blocks having similar health grades. Physical blocks having similar health grades may have similar wear leveling conditions.

In various examples, the virtual block management component 112 may determine a health grade for each physical block based on the collected read errors. The virtual block management component 112 may reform the virtual blocks based on the health grades. The virtual block management component 112 may dynamically reform the virtual blocks based on certain trigger conditions, such as a request for a new virtual block, a number of read errors for a virtual block exceeding a threshold, a drive utilization for a virtual block exceeding a threshold, or periodically at specified times, without limitation. The drive utilization for the virtual block may refer to a number of program/erase cycles of the virtual block. Each reformed virtual block may include a set of physical blocks having the same health grades or health grades within a threshold range of each other or of a specified health grade. Accordingly, write amplification may be decreased, which, in turn, may increase write throughput, decrease read and write latency, and extend the lifespan of the memory device 114.

In an example, the virtual block management component 112 may monitor a first virtual block. The first virtual block may include a first subset of the physical blocks of the NVM media 116. After determining the health grades, the virtual block management component 112 may determine that the first subset of the physical blocks have varying health grades. In response to the determination, or regardless of the determination (e.g., where reformation is not contingent on a determination of variance within the first subset) the virtual block management component may reform the first virtual block to include a second subset of the plurality of physical blocks. The second subset of the plurality of physical blocks may include none or some of the first subset of the plurality of physical blocks. The second subset of the plurality of physical blocks may have health grades that are within a threshold range of each other or of a given health grade. In some examples, the second subset may have identical health grades. Consequently, the first virtual block may be reformed to maintain efficient operation by removing unhealthy physical blocks.

In conventional memory devices, the physical blocks may undergo a predefined number of program/erase cycles before the physical blocks are retired. The predetermined number of program/erase cycles for a particular memory device may be determined by a of the particular memory device and may vary based on a memory type of the particular memory device. However, some of the physical blocks may be healthy after the number of program/erase cycles has been surpassed by the physical blocks. Accordingly, dynamically reforming the virtual blocks based on the health grades of the physical blocks may enable healthy physical blocks to extend the lifetime of the memory device 114 by preventing retirement of healthy blocks.

The virtual block management component 112 may generate and store a map of each virtual block. The map may include physical and/or logical addresses of the physical blocks making up each virtual block. The controller may update the map each time one or more virtual blocks are reformed to include updated physical and/or logical address of the physical blocks making up each virtual block.

In various examples, instructions for executing the virtual block management component 112 may be stored in the local memory 110. Some or all functions of the virtual block management component 112 may be executed by the processor 108, the local controller(s) 118, other circuitry of the controller 106 and/or memory device 114, or a combination thereof.

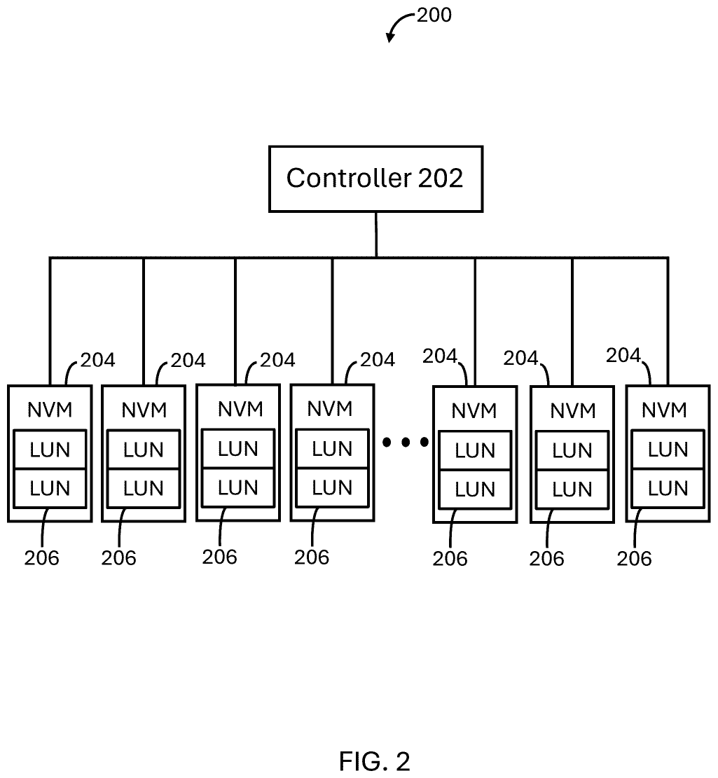

FIG. 2 illustrates an example data storage system 200 including a controller 202 and a plurality of NVM media 204. In various examples, the data storage system 200 may correspond to the data storage system 104 of FIG. 1, the controller 202 may correspond to the controller 106 of FIG. 1, and the NVM media 204 may correspond to the NVM media 116 of FIG. 1, without limitation. In various examples, the NVM media 204 may each include two LUNs 206.

In various examples, a plurality of virtual blocks of the present disclosure may be formed across each LUN 206 of each NVM 204. Each LUN 206 may correspond to a respective die of a respective NVM 204. Each virtual block may include one physical block from each LUN 206 of each NVM 204. The controller 202 may dynamically reform the virtual block based on determining health grades of each of the physical blocks, as discussed throughout this disclosure.

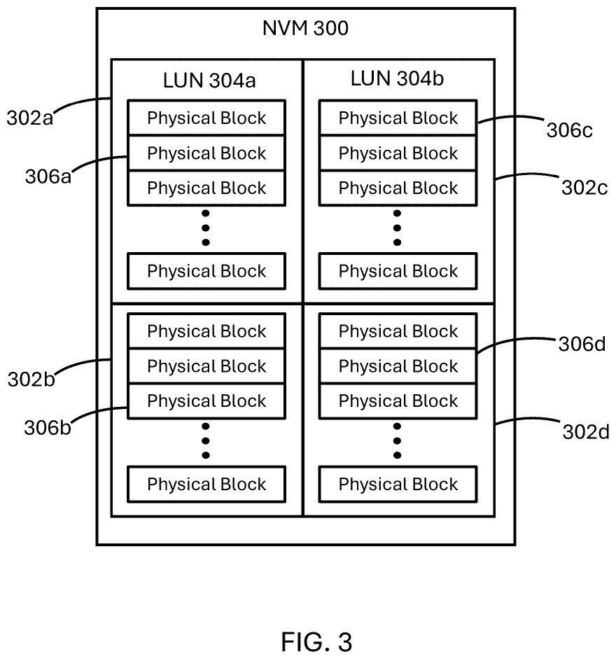

FIG. 3 illustrates an example NVM media 300. The NVM 300 may correspond to the NVM media 116 of FIG. 1 and/or the NVM media 204 of FIG. 2, without limitation. The NVM media 300 may include LUN 304a and LUN 304b. LUN 304 The LUN 304a may include a plane 302a and a plane 302b. The plane 302a may include physical blocks 306a. The plane 302b may include physical blocks 306b. The LUN 304b may include a plane 302c and a plane 304d. The plane 302c may include physical blocks 306c. The plane 302d may include physical blocks 306d. Although each LUN 304a, 304b is shown to include two planes, each LUN 304a, 304b may include more planes, such as four (4), six (6), or eight (8) planes, without limitation.

In various examples, a virtual block may include one physical block 306a, 306b, 306c, 306d from each of the dies (or LUNs) 304a, 304b. In an example, a first virtual block may include a first physical block 306a of the plane 302a, a first physical block 306b of the plane 302b, a first physical block 306c of the plane 302c, and a first physical block 306d of plane 302d. If it is determined that the first physical block 306a and the first physical block 306b have different health grades, the virtual block may be dynamically reformed to include the first physical block 306a and a second physical block 306b of the plane 302b. One of ordinary skill will appreciate that any combination of physical blocks may be made during reformation, and that any of a variety of triggering events for reformation may occur, without departing from the scope of the examples described herein.

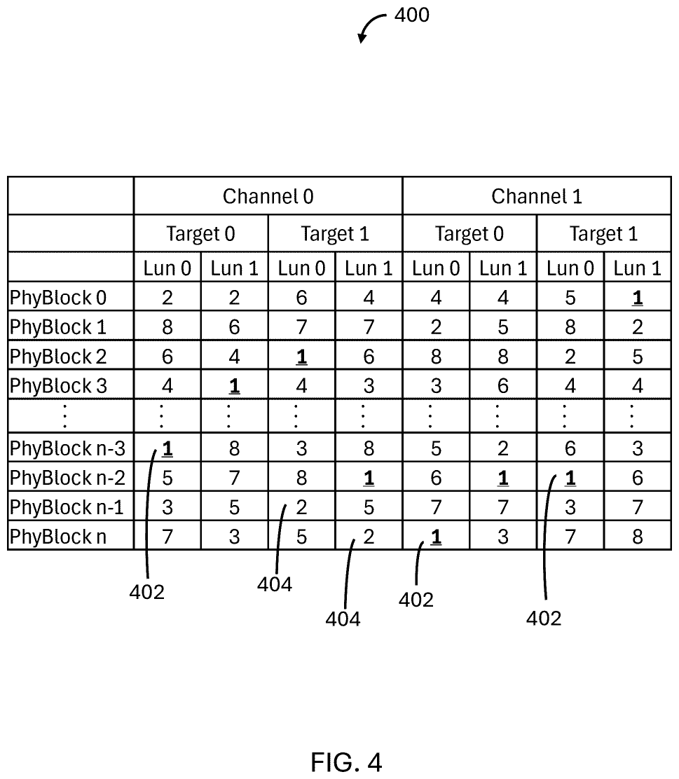

FIG. 4 illustrates an example diagram 400 of virtual blocks formed based on physical memory block health. Each physical block may be given a health grade, as discussed above. In this example, for the sake of simplicity, the health grades may range in value between one (1) and eight (8). Each virtual block may include a subset of physical blocks. The subsets of physical blocks may respectively include one or more physical blocks from each LUN. Specifically, each virtual block may include one physical block from each LUN. The LUNs may span across a plurality of targets and a plurality of channels. In the present example, two channels are shown, with two targets in each channel and two LUNs in each target. In various examples, the LUNs may span a plurality of channels, such as four (4), eight (8), sixteen (16), thirty-two (32), or sixty-four (64) channels, without limitation. In various examples, each channel may include two or more targets with two or more LUNs included in each target. In some examples, one or more virtual blocks may include more than one physical block from one or more LUNs and may not include any blocks from one or more other LUNs.

In an example, a virtual block 402 is formed from all physical blocks having a health grade value of one (1). Another virtual block 404 is formed from all physical blocks having a health grade value of two (2), and so on. Accordingly, each virtual block may be formed from physical blocks having similar or identical health grades. In various examples, the health grades may not be an integer. In various examples, the physical blocks of a given virtual block may have health grades that are within a threshold range of each other.

In various examples, the virtual blocks may be dynamically reformed based on changes to the health grades of the physical blocks. Each time a particular virtual block is reformed, the reformed virtual block may include at least some of the physical blocks that were previously included in that virtual block. In some examples, the reformed virtual block may include all but one of the physical blocks that were previously included in that virtual block. In other examples, the reformed block may not include any physical blocks that were previously included in that virtual block.

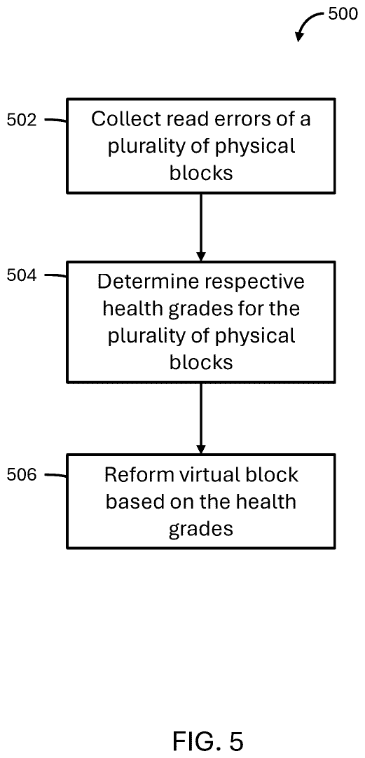

FIG. 5 illustrates an example method for dynamically forming virtual blocks based on physical block health. The method may be performed by a controller (e.g. the controller 106 and/or controller(s) 118 of FIG. 1) of a memory storage system (e.g. the data storage system 104 of FIG. 1). The controller may manage storage and retrieval of data to and from a memory device (e.g. the memory device 114 of FIG. 1). The controller may receive read and write requests from a host system. Upon receiving a write request, the controller may facilitate writing data received from the host system to the memory device. Upon receiving a read request, the controller may facilitate reading of data from the memory device and communication of the data to the host system.

The memory device may include a plurality of physical blocks. The controller may organize the memory device into a plurality of virtual blocks. The controller may form a respective subset of the plurality of physical blocks into a given virtual block. The controller may generate and store a map of each virtual block. The map may include physical and/or logical addresses of the physical blocks making up each virtual block. The controller may update the map each time one or more virtual blocks are reformed to include updated physical and/or logical address of the physical blocks making up each virtual block.

At operation 502, read errors of the plurality of physical blocks may be collected. A read error may be produced by a given physical block during a read operation. In various examples, a portion of the physical blocks may produce read errors during a read operation and other physical blocks may not produce read errors during the read operation. The read errors may be collected when performing a read operation associated with a read request received from the host. Additionally or alternatively, the controller may perform a background scan to collect the read errors. The background scan may perform background read operations to detect and collect read errors produced by respective physical blocks of the plurality of blocks. It would be appreciated by one of ordinary skill in the art that various different background scans, such as a patrol read scan or another dedicated background read scan, may be utilized to collect the read errors. The virtual block may include a first subset of the plurality of physical blocks. The collected read errors may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. The collected read errors may include additional information associated with the physical blocks, such as a program/erase cycle count, usage statistics, and/or other relevant information.

In various examples, a drive utilization of the virtual block may be monitored. The drive utilization may correspond to a number of P/E cycles associated with the physical blocks of the virtual block. The drive utilization may be associated with a utilization threshold. In various examples, health grades for the first subset of the physical blocks may be determined in response to determining the drive utilization of the virtual block has reached or exceeded the threshold. The utilization threshold may be adjustable and may be determined based on a type of memory device. Different types of memory devices may be associated with different numbers of P/E cycles before degradation occurs.

At operation 504, respective health grades for the physical blocks may be determined. The respective health grades may be determined based on the collected read errors. In various examples, the health grades may be determined for subsets of the physical blocks associated with virtual blocks having a drive utilization exceeding the utilization threshold. Alternatively or additionally, health grades for each physical block of the memory device may be determined periodically.

At operation 506, a virtual block may be reformed based on the health grades. The virtual block may be reformed into a reformed virtual block. The reformed virtual block may include a second subset of the plurality of physical blocks. The second subset of the physical blocks may include at least some of the first subset of the physical blocks. In some examples, the second subset of the physical blocks may include one or more physical blocks from the first subset. The second subset of the physical blocks may have health grades that are within a threshold range of each other and/or of a given health grade value. In some examples, the second subset of the physical blocks may have identical health grades.

In various examples, a plurality of the virtual blocks of the memory device may be dynamically reformed based on the health grades of the physical blocks. Each reformed virtual block may include respective subsets of the physical blocks. The physical blocks of a particular respective subset may have health grades that are within a threshold range of each other and/or of a given health grade value. In some examples, the physical blocks of a particular respective subset may have identical health grades. Accordingly, write amplification may be decreased, which, in turn, may increase write throughput, decrease read and write latency, and extend the lifespan of the memory device.

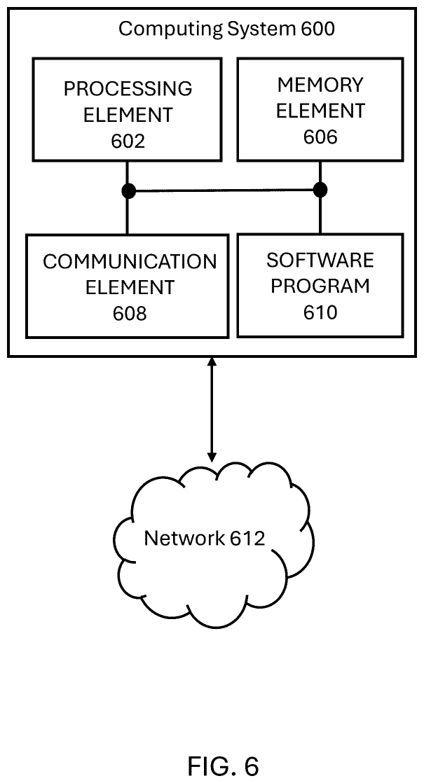

FIG. 6 illustrates a computing system 600 connected to a communication network 612. The computing system 600 may include at least one processing element 602, at least one memory element 606, a communication element 608, and a software program 610. In various examples, the computing system 600 may be a host system (e.g. the host system 102 of FIG. 1) and/or a data storage system (e.g. the data storage system 104 of FIG. 1), without limitation.

The software program 610 may be configured with instructions for performing and/or enabling performance of at least some of the steps set forth herein. In an embodiment, the software program 610 comprises instructions stored on computer-readable media of memory element 606. In various examples, the software program 610 may include instructions for performing operations of the virtual block management component 112 discussed with reference to FIG. 1.

The communication network 612 generally allows communication between the computing system 600 and another computing device, such as between a remote host system (e.g. the host system 102), a local host system, and/or a data storage system (e.g. the data storage system 104 of FIG. 1), without limitation.

The communication network 612 may include the Internet, cellular communication networks, local area networks, metro area networks, wide area networks, cloud networks, plain old telephone service (POTS) networks, and the like, or combinations thereof. The communication network 612 may be wired, wireless, or combinations thereof and may include components such as modems, gateways, switches, routers, hubs, access points, repeaters, towers, and the like. The computing system 600 may, for example, connect to the communication network 612 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 608 generally allow communication between the computing system 600 and the communication network 612. The communication element 608 may include signal or data transmitting and receiving circuits, such as antennas, amplifiers, filters, mixers, oscillators, digital signal processors (DSPs), and the like. The communication element 608 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard such as WiFi, IEEE 802.16 standard such as WiMAX, Bluetooth™, or combinations thereof. In addition, the communication element 608 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 608 may establish communication through connectors or couplers that receive metal conductor wires or cables, like Cat 6 or coax cable, which are compatible with networking technologies such as ethernet. In certain embodiments, the communication element 608 may also couple with optical fiber cables. The communication element 608 may respectively be in communication with the processing element 602 and/or the memory element 606.

The memory element 606 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some embodiments, the memory element 606 may be embedded in, or packaged in the same package as, the processing element 602. The memory element 606 may include, or may constitute, a “computer-readable medium.” The memory element 606 may store the instructions, code, code segments, software, firmware, programs, applications, apps, services, daemons, or the like that are executed by the processing element 602. In an embodiment, the memory element 606 respectively store the software applications/program 610. The memory element 606 may also store settings, data, documents, sound files, photographs, movies, images, databases, and the like. In various examples, the memory element 606 may include a first memory component (e.g. the local memory 110 of FIG. 1) and one or more SSDs (e.g. the memory device 114 of FIG. 1).

The processing element 602 may include electronic hardware components such as processors. The processing element 602 may include digital processing unit(s). The processing element 602 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 602 may generally execute, process, or run instructions, code, code segments, software, firmware, programs, applications, apps, processes, services, daemons, or the like. For instance, the processing element 602 may respectively execute the software applications/program 610. The processing element 602 may also include hardware components such as finite-state machines, sequential and combinational logic, and other electronic circuits that can perform the functions necessary for the operation of the current disclosure. The processing element 602 may be in communication with the other electronic components through serial or parallel links that include universal busses, address busses, data busses, control lines, and the like.

Through hardware, software, firmware, or various combinations thereof, the processing element 602 may—alone or in combination with other processing elements—be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

According to various examples of the present disclosure, non-transitory computer readable media may include instructions stored thereon, that when executed by at least one processor, cause the at least one processor to: collect read errors of a plurality of physical blocks, a subset of said plurality of physical blocks being formed into a virtual block; determine respective health grades for the plurality of physical blocks based on the collected read errors; and based on the respective health grades, reform the virtual block into a reformed virtual block, said reformed virtual block including a second subset of the plurality of physical blocks.

In combination with any of the previous examples, the health grades of the second subset of the plurality of physical blocks may be within a threshold range of each other.

In combination with any of the previous examples, the second subset of the plurality of physical blocks may include at least some of the first subset of the plurality of physical blocks.

In combination with any of the previous examples, the collected read errors may include a number of uncorrectable read errors, a number of correctable read errors, and a number of error bits in each of the correctable read errors.

In combination with any of the previous examples, the determination of the health grades may be contingent on or triggered by a determination that a drive utilization of the virtual block has exceeded a utilization threshold.

In combination with any of the previous examples, the instructions, when executed by the at least one processor, may cause the at least one processor to dynamically form a plurality of additional reformed virtual blocks based on the respective health grades. The plurality of additional reformed virtual blocks may include respective additional subsets of the physical blocks. The health grades of the respective additional subsets of the physical blocks may be within a threshold range of each other.

In combination with any of the previous examples, the read errors may be collected during one of: a read operation, a background scan, and a combination thereof.

According to various examples of the present disclosure, a system may include a plurality of physical blocks and a controller. A first subset of the plurality of physical blocks may be formed into a virtual block. The controller may include a memory and at least one processor. The memory may include instructions that, when executed by the at least one processor, cause the at least one processor to: collect read errors of the plurality of physical blocks; determine respective health grades for the plurality of physical blocks based on the collected read errors; and, based on the respective health grades, reform the virtual block into a reformed virtual block, said reformed virtual block including a second subset of the plurality of physical blocks.

In combination with any of the previous examples, the health grades of the second subset of the plurality of physical blocks may be within a threshold range of each other.

In combination with any of the previous examples, the second subset of the plurality of physical blocks may include at least some of the first subset of the plurality of physical blocks.

In combination with any of the previous examples, the collected read errors may include a number of uncorrectable read errors, a number of correctable read errors, a number of error bits in each of the correctable read errors, and error correction data.

In combination with any of the previous examples, the determination of the health grades may be contingent on or triggered by a determination that a drive utilization of the virtual block has exceeded a utilization threshold.

In combination with any of the previous examples, the instructions, when executed by the at least one processor, may cause the at least one processor to dynamically form a plurality of additional reformed virtual blocks based on the respective health grades. The plurality of additional reformed virtual blocks may include respective additional subsets of the physical blocks. The health grades of the respective additional subsets of the physical blocks may be within a threshold range of each other.

In combination with any of the previous examples, the read errors may be collected during one of: a read operation, a background scan, and a combination thereof.

According to various examples of the present disclosure, a computer-implemented method may include collecting read errors of a plurality of physical blocks, a first subset of the plurality of physical blocks being formed into the virtual block; determining respective health grades for the plurality of physical blocks based on the collected read errors; and based on the respective health grades, reforming the virtual block into a reformed virtual block, said reformed virtual block including a second subset of the plurality of physical blocks.

In combination with any of the previous examples, the health grades of the second subset of the plurality of physical blocks may be within a threshold range of each other.

In combination with any of the previous examples, the second subset of the plurality of physical blocks may include at least some of the first subset of the plurality of physical blocks.

In combination with any of the previous examples, the read errors may be collected during one of: a read operation, a background scan, and a combination thereof. The collected read errors may include a number of uncorrectable read errors, a number of correctable read errors, a number of error bits in each of the correctable read errors, and error correction data.

In combination with any of the previous examples, the determination of the health grades may be contingent on or triggered by a determination that a drive utilization of the virtual block has exceeded a utilization threshold.

In combination with any of the previous examples, the method may include dynamically forming a plurality of additional reformed virtual blocks based on the respective health grades. The plurality of additional reformed virtual blocks may include respective additional subsets of the physical blocks. The health grades of the respective additional subsets of the physical blocks may be within a threshold range of each other.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112 (f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. Non-transitory computer readable media having instructions stored thereon, that when executed by at least one processor, cause the at least one processor to:
collect read error data of a plurality of physical blocks, a first subset of said plurality of physical blocks being formed into a virtual block;
determine respective health grades for the plurality of physical blocks based on the collected read errors; and
based on the respective health grades, reform the virtual block into a reformed virtual block, said reformed virtual block including a second subset of the plurality of physical blocks.

2. The non-transitory computer readable media of claim 1,
wherein the health grades of the second subset of the plurality of physical blocks are within a threshold range of each other.

3. The non-transitory computer readable media of claim 1,
wherein the second subset of the plurality of physical blocks includes at least some of the first subset of the plurality of physical blocks.

4. The non-transitory computer readable media of claim 1,
wherein the collected read errors include a number of uncorrectable read errors, a number of correctable read errors, a number of error bits in each of the correctable read errors, and error correction data.

5. The non-transitory computer readable media of claim 1,
wherein the determination of the health grades is contingent on or triggered by a determination that a drive utilization of the virtual block has exceeded a utilization threshold.

6. The non-transitory computer readable media of claim 1,
wherein the instructions, when executed by the at least one processor, cause the at least one processor to:
dynamically form a plurality of additional reformed virtual blocks based on the respective health grades,
said plurality of additional reformed virtual blocks including respective additional subsets of the physical blocks,
wherein the health grades of the respective additional subsets of the physical blocks are within a threshold range of each other.

7. The non-transitory computer readable media of claim 1,
wherein the read error data is collected during one of: a read operation, a background scan, and a combination thereof.

8. A system comprising:
a plurality of physical blocks, a first subset of said plurality of physical blocks being formed into a virtual block; and
a controller including a memory and at least one processor, said memory including instructions, that, when executed by the at least one processor, cause the at least one processor to:
collect read errors of the plurality of physical blocks,
determine respective health grades for the plurality of physical blocks based on the collected read errors, and
based on the respective health grades, reform the virtual block into a reformed virtual block, said reformed virtual block including a second subset of the plurality of physical blocks.

9. The system of claim 7,
wherein the health grades of the second subset of the plurality of physical blocks are within a threshold range of each other.

10. The system of claim 7,
wherein the second subset of the plurality of physical blocks includes at least some of the first subset of the plurality of physical blocks.

11. The system of claim 7,
wherein the collected read errors include a number of uncorrectable read errors, a number of correctable read errors, a number of error bits in each of the correctable errors, and error correction data.

12. The system of claim 7,
wherein the determination of the health grades is contingent on or triggered by a determination that a drive utilization of the virtual block has exceeded a utilization threshold.

13. The system of claim 7,
wherein the instructions, when executed by the at least one processor, cause the at least one processor to:
form a plurality of additional reformed virtual blocks based on the respective health grades,
said plurality of additional reformed virtual blocks including respective additional subsets of the physical blocks,
wherein the health grades of the respective additional subsets of the physical blocks are within a threshold range of each other.

14. The system of claim 7,
wherein the read errors are collected during one of: a read operation, a background scan, and a combination thereof.

15. A computer-implemented method comprising:
collecting errors of a plurality of physical blocks, a first subset of said plurality of physical blocks being formed into a virtual block;
determining respective health grades for the plurality of physical blocks based on the collected read errors; and
based on the respective health grades, reforming the virtual block into a reformed virtual block, said reformed virtual block including a second subset of the plurality of physical blocks.

16. The computer-implemented method of claim 14,
wherein the health grades of the second subset of the plurality of physical blocks are within a threshold range of each other.

17. The computer-implemented method of claim 14,
wherein the second subset of the plurality of physical blocks includes at least some of the first subset of the plurality of physical blocks.

18. The computer-implemented method of claim 14,
wherein the read errors are collected during one of: a read operation, a background scan, and a combination thereof,
wherein the collected read errors include a number of uncorrectable read errors, a number of correctable read errors, a number of error bits in each of the correctable errors, and error correction data.

19. The computer-implemented method of claim 14,
wherein the determination of the health grades is contingent on or triggered by a determination that a drive utilization of the virtual block has exceeded a utilization threshold.

20. The computer-implemented method of claim 18 including—
forming a plurality of additional reformed virtual blocks based on the respective health grades,
said plurality of additional reformed virtual blocks including respective additional subsets of the physical blocks,
wherein the health grades of the respective additional subsets of the physical blocks are within a threshold range of each other.
